(19) United States
(12) Patent Application Publication
(10) Pub. No.: US 2013/0003314 A1
(43) Pub. Date: Jan. 3, 2013

(54) MULTILAYER PRINTED CIRCUIT BOARD AND MANUFACTURING METHOD THEREFOR

(75) Inventors: Yusuke Igarashi, Isesaki-shi (JP); Takeshi Nakamura, Isesaki-shi (JP)

(73) Assignee: SANYO ELECTRONIC CO., LTD., Moriguchi-shi (JP)

(21) Appl. No.: 13/578,791

(22) PCT Filed: Feb. 21, 2011
(86) PCT No.: PCT/JP2011/054420

§ 371 Date: Sep. 10, 2012

(30) Foreign Application Priority Data
Feb. 22, 2010 (JP) 2010-36239
Feb. 14, 2011 (JP) 2011-028582

(51) Int. Cl. H05K 1/03; H05K 3/10; H05K 7/06

(52) U.S. Cl. 361/719; 174/251; 361/783; 29/850

(57) ABSTRACT

Provided is a substrate wherein wiring layers laminated onto the top and bottom surfaces of a core layer are connected to each other by a simple means. Also provided is a method for manufacturing said substrate. In the provided substrate (10A), a connection substrate (13) is placed in a removed region (12) which goes all the way through a part of a thick core layer (11). Said connection substrate (13) electrically connects a first wiring layer (16A) laminated onto the top surface of the core layer (11) to a second wiring layer (16B) laminated onto the bottom surface of the core layer (11). This eliminates the requirement of providing a through-hole through the core layer (11) for each connection, resulting in a small form-factor substrate (10A) with a high wiring density.

### REFERENCE TO RELATED APPLICATIONS

This application is a national stage application under 35 USC 371 of International Application No. PCT/JP2011/054420, filed Feb. 21, 2011, which claims the priority of Japanese Patent Application No. 2010-36239, filed Feb. 22, 2010, and Japanese Patent Application No. 2011-028582, filed Feb. 14, 2011, the entire contents of which are incorporated herein by reference.

### FIELD OF THE INVENTION

The present invention relates to a multilayer printed circuit board and a method of manufacturing the same, and particularly relates to a multilayer printed circuit board and a method of manufacturing the same, in which a multilayered wiring layer is stacked on both an upper surface and a lower surface of a core layer.

### BACKGROUND OF THE INVENTION

Recent electronic devices offer higher performances and are smaller in size than before, and the significance of heat dissipation has been elevated by an increase in the capacities of components mounted on a mounting board and by an increase in the density of the mounting board itself. For this reason, for example, a board including a core layer having excellent heat release performance and uniform heat distribution is used (refer to Patent Document 1, for example).

The configuration of a board 100 including a core layer is described referring to the sectional view in FIG. 7. The board 100 includes a core layer 111, a first wiring layer 116A stacked on an upper surface of the core layer with a first insulating layer 114A interposed therebetween, and a second wiring layer 116B stacked on a lower surface of the core layer 111 with a second insulating layer 114B interposed therebetween.

The core layer 111 is a plate-shaped body made of metal such as copper or aluminum and having a thickness of about 100 μm to 200 μm. The core layer 111 provides the overall mechanical strength of the board 100 and functions to improve heat release through the board 100. Accordingly, heat released from a circuit element, such as a transistor, mounted on an upper surface of the board 100 is dissipated well to the outside through the core layer 111.

The first wiring layer 116A and the second wiring layer 116B are formed by patterning copper foil or the like into predetermined shapes, and are isolated from the core layer by the insulating layers made of a resin.

The first wiring layer 116A and the second wiring layer 116B are electrically connected to each other via the inside of a through-hole 121 provided to penetrate the core layer 111. Specifically, first, the through-hole 121 is formed by partially removing the core layer 111. Then, the through-hole 121 is filled with a resin material forming the first resin layer 114A and the second resin layer 116B, and a connection portion 125 is formed by further penetrating this filling resin material. Through the connection portion 125, the first wiring layer 116A formed on the upper surface of the core layer 111 is electrically connected to the second wiring layer 116B formed on the lower surface of the core layer 111.
Patent Document 1: Japanese Patent Application Publication No. 2007-294932

### SUMMARY OF THE INVENTION

However, a diameter L10 of the above-described through-hole 121 provided in the board 100 is about 0.4 mm for example, and the width of the connection portion 125 arranged inside the through-hole 121 is about 0.1 mm for example. It is difficult to further reduce the sizes of the through-hole 121 and the connection portion 125 because they are formed through wet etching, laser irradiation, and plating.

For this reason, even when the first wiring layer 116A and the second wiring layer 116B are formed with a fine line width of about 50 μm to 100 μm, a further reduction in the overall size of the board 100 is difficult since the through-hole 121 and the connection portion 125 occupy a large area of the board 100.

In addition to this problem, to connect the first wiring layer 116A and the second wiring layer 116B at multiple connection locations, the through-hole 121 and the connection portion 125 have to be formed for each of these connection locations. In such a case, a size reduction of the board 100 is even more difficult.

The present invention has been made in consideration of the above problems, and a main objective of the present invention is to provide a board having a configuration in which wiring layers staked on an upper surface and a lower surface of a core layer, respectively, are connected to each other by simple means, and to provide a manufacturing method thereof.

A board of the present invention comprises: a core layer having a first main surface and a second main surface; a first wiring layer stacked on the first main surface of the core layer with a first insulating layer interposed therebetween; a second wiring layer stacked on the second main surface of the core layer with a second insulating layer interposed therebetween; a removed area provided to penetrate part of the core layer; a connection board being arranged in the removed area and including a plurality of layers of wiring patterns, the connection board functioning as a path connecting the first wiring layer and the second wiring layer, wherein a first wiring pattern of the connection board located at the first main surface side of the core layer is connected to the first wiring layer via a first connection portion provided to penetrate the first insulating layer, and a second wiring pattern of the connection board located at the second main surface side of the core layer is connected to the second wiring layer via a second connection portion provided to penetrate the second insulating layer.

A method of manufacturing a board of the present invention comprises the steps of: preparing a core layer having a first main surface, a second main surface, and a removed area provided to penetrate part of the core layer; arranging a connection board in the removed area of the core layer, the connection board having a first wiring pattern provided at the first main surface side and a second wiring pattern provided at the second main surface side; and stacking a first wiring layer on the first main surface of the core layer with a first insulating layer interposed therebetween, stacking a second wiring layer on the second main surface of the core layer with a second insulating layer interposed therebetween, and electrically connecting the first wiring layer to the second wiring layer via the connection board.

According to the present invention, a removed area is provided by partially removing a core layer, and via a connection board arranged in this removed area, a first wiring layer stacked on an upper surface of the core layer is electrically connected to a second wiring layer stacked on a lower surface of the core layer. Accordingly, there is no need for providing a through-hole in the core layer for each of locations where the wiring layers are to be connected to each other. This reduces the overall area occupied by connection means that connects the wiring layers to each other, and thereby improves high wiring density of the board.

Further, multilayered wiring patterns provided in the connection board are formed finer than the wiring layers stacked on the core layer. For this reason, part of an electric circuit configured by the wiring layers stacked on the core layer in the prior art can be instead configured by the wiring patterns included in the connection board 13. This contributes to a further size reduction of the board.

Furthermore, a manufacturing cost for the board is reduced because steps required for providing connection means that penetrate the core layer, such as a laser irradiation step and a plated-film formation step, are unnecessary in the manufacturing method.

### BRIEF DESCRIPTION OF THE DRAWINGS

FIG. 1 includes views showing a board of the present invention. FIG. 1A is a sectional view, and FIG. 1B is a perspective view.

FIG. 2 includes views partially showing a board of the present invention. FIG. 2A is a sectional view partially showing the board, FIG. 2C is a perspective view showing a connection board used, and FIG. 2C is a plan view showing the connection board in an enlarged manner.

FIGS. 3A and 3B are sectional views showing another embodiment of a board of the present invention, and FIG. 3C is a sectional view showing a circuit device employing the board of the present invention.

FIG. 4 is a sectional view showing another embodiment of a board of the present invention.

FIGS. 5A to 5D are sectional views showing a method of manufacturing a board of the present invention.

FIGS. 6A to 6C are sectional views showing the method of manufacturing a board of the present invention.

FIG. 7 is a sectional view showing a board of a prior art.

FIGS. 8A to 8C are sectional views showing a method of manufacturing a board of the present invention.

FIG. 9 includes views explaining a board of the present invention.

### DETAILED DESCRIPTION OF THE INVENTION

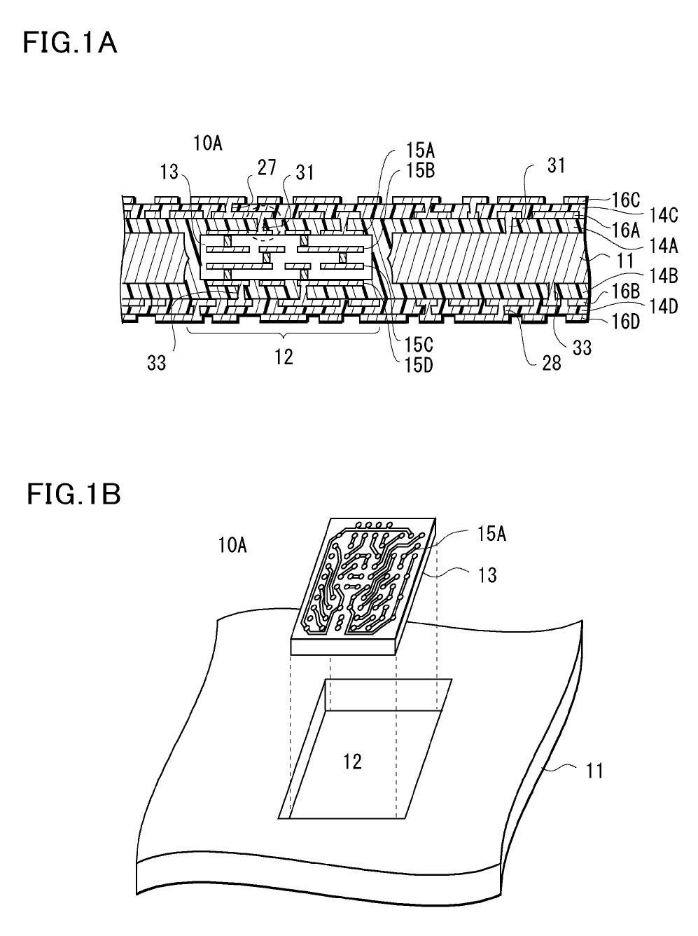

Referring to FIG. 1, the configuration of a board 10A of the present embodiment is described. FIG. 1A is a sectional view showing the configuration of the board 10A, and FIG. 1B is a perspective view schematically showing the board 10A.

Referring to FIG. 1A, the board 10A includes a thick core layer 11, wiring layers (a first wiring layer 16A and a third wiring layer 16C) stacked on an upper surface of the core layer 11 with insulating layers interposed, wiring layers (a second wiring layer 16B and a fourth wiring layer 16D) stacked on a lower surface of the core layer 11 with insulating layers interposed, and a connection board 13 embedded in a removed area 12 of the core layer 11.

Although multilayered wiring having a total of four layers is formed on the upper and lower main surfaces of the core layer 11 here, the number of the wiring layers to be stacked is not limited to four layers. Two wiring layers or six or more wiring layers may be formed.

The core layer 11 functions as a layer configured to enhance the mechanical strength of the board 10A and to improve the heat release performance of the board 10A. The core layer 11 is formed thicker than the wiring layers, and has a thickness of for example, 100 μm to 200 μm. A material usable for the core layer 11 is metal containing copper as its main component, metal containing aluminum as its main component, an alloy, or the like. In addition, as a material for the core layer 11, use of rolled metal, such as rolled copper foil, can further improve the mechanical strength and the heat release performance of the core layer 11.

If aluminum is used as a material for the core layer 11, the upper and lower surfaces of the core layer 11 may be coated with an alumite film formed by oxidizing aluminum. Like Cu, Al easily bends if its thickness is small. For this reason, if the Al layer is provided with a hard layer mainly formed of aluminum oxide and therefore made of the same material as the Al layer, the Al layer can be resistant to bending. Consequently, provision of the hard layer offers resistance against deformation, and therefore allows the board 10A itself to be maintained to be flat.

Further, the core layer 11 may be used as a signal pattern through which electrical signals inputted to and outputted from each of the wiring layers pass, or as a pattern for extracting a fixed potential (e.g., a power supply potential or a ground potential) at a predetermined location.

Here, a material other than metal can be used as the material for the core layer 11, and an inorganic material, such as ceramic, or a resin material, such as a glass epoxy substrate, can also be used.

A first insulating layer 14A and a second insulating layer 14B cover the upper surface and the lower surface of the core layer 11, respectively. The thickness of each of the first insulating layer 14A and the second insulating layer 14B covering the core layer 11 is, for example, 50 μm to 100 μm. A material usable for the first insulating layer 14A and the second insulating layer 14B is a thermosetting resin, such as an epoxy resin, or a thermoplastic resin, such as a polyethylene resin.

The heat resistance of the first insulating layer 14A and the second insulating layer 14B is decreased by using, for these insulating layers, a resin material filled with a fibrous or particulate filler. Moreover, by mixing a filler into the first insulating layer 14A and the second insulating layer 14B, the coefficient of thermal expansion of these insulating layers comes closer to that of the core layer 11 made of metal, preventing a warp of the board caused when the board experiences a thermal change. A material usable for the filler is alumina, silicon oxide, or a silicon nitride.

The first wiring layer 16A is a wiring layer formed on an upper surface of the first insulating layer 14A, and is formed by selectively etching a conductive film or a plated film attached to the first insulating layer 14A. The L/S of the first wiring layer 16A can be as fine as 50 μm/50 μm to 100 μm/100 μm, for example.

Here, L/S indicates the fineness of the wiring. When the L/S is 20 μm/20 μm, the width (L: line) of each wiring line is 20 μm and the distance (S: space) between the wiring lines is 20 μm.

The first wiring layer 16A is electrically connected to the core layer 11 via connection portions 31 provided to penetrate the first insulating layer 14A. Such configuration allows the core layer 11 to be used as a layer for routing the ground potential.

The second wiring layer 16B is a wiring layer formed on a lower surface of the second insulating layer 14B, and has the same configuration as the first wiring layer 16A described above. Further, the second wiring layer 16B is electrically connected to the lower surface of the core layer 11 via connection portions 33 provided to penetrate the second insulating layer 14B.

The connection portions 31 and the connection portions 33 are made of a conductive material, such as a plated film or a conductive paste, formed in through-holes which are provided by removing the insulating layers, and function to connect the corresponding wiring layers to the core layer 11. Here, the first wiring layer 16A and the core layer 11 are connected to each other via the connection portions 31 provided to penetrate the first insulating layer 14A, and the second wiring layer 16B and the core layer 11 are connected to each other via the connection portions 33 provided to penetrate the second insulating layer 14B.

The connection portions may function as paths through which electrical signals pass, or may be so-called dummy paths through which no electrical signal pass. Even when the connection portions 31 and the like are ones that do not allow electrical signals to pass therethrough, they can still be used as thermal via holes through which heat passes.

The third wiring layer 16C is stacked on the upper surface of the first wiring layer 16A with a third insulating layer 14C interposed therebetween. The details of the first insulating layer 14A and the third wiring layer are the same as those of the first insulating layer 14A and the first wiring layer 16A descried above. The third wiring layer 16C and the first wiring layer 16A are electrically connected to each other at predetermined locations via connection portions 27 penetrating the third insulating layer 14C.

Circuit elements such as an IC are connected to the third wiring layer 16C being the uppermost wiring layer. The upper surfaces of the third wiring layer 16C and the third insulating layer 14C may be covered with a solder resist, except for the portions of the third wiring layer 16C which are to be connected with the circuit elements. Such configuration prevents solder used in mounting of the elements from being attached to the third wiring layer 16C, which in turn prevents a short circuit between the wiring lines occurring in the mounting step.

The fourth wiring layer 16D is formed on a lower surface of the second wiring layer 16B with a fourth insulating layer 14D interposed therebetween. The details of the fourth insulating layer 14D and the fourth wiring layer 16D are the same as those of the second insulating layer 14B and the second wiring layer 16B described above. The second wiring layer 16B and the fourth wiring layer 16D are electrically connected to each other via connection portions 28 formed to penetrate the fourth insulating layer 14D. An external connection electrode, such as a solder ball, may be formed on the fourth wiring layer 16D being the lowermost layer. Further, the lower surfaces of the fourth wiring layer 16D and the fourth insulating layer 14D may be covered with a solder resist, except for the portion of the fourth insulating layer 14D which is to be the connection location.

The connection board 13 is a multilayer board housed in the removed area 12 which is provided by partially removing the core layer 11, and functions as connection means that connects the wiring layers stacked on the upper surface of the core layer 11 to the wiring layers stacked on the lower surface of the core layer 11.

Specifically, the connection board 13 includes multilayered wiring patterns stacked with insulating materials such as a glass epoxy resin and ceramic interposed. Namely, the connection board 13 is provided with, from up to down, a first wiring pattern 15A, a second wiring pattern 15B, a third wiring pattern 15C, and a fourth wiring pattern 15D. These wiring patterns are connected to each other at predetermined locations by penetrating the insulating materials.

The connection board 13 has the same thickness as the core layer 11, and is 100 μm to 200 μm thick, for example. Referring to FIG. 1B, the removed area 12 having a square shape in a plan view is provided in the core layer 11 by performing partial etching or pressing on the core layer 11, and the connection board 13 is housed in this removed area 12. The size of the connection board 13 in a plan view is smaller than that of the removed area 12 provided in the core layer 11. Referring to FIG. 1A, the connection board 13 is spaced away from side surfaces of the core layer 11 which face the removed area 12. Surfaces of the connection board 13 housed in the removed area 12 are covered with the resin material forming the first insulating layer 14A and the resin material forming the second insulating layer 14B, respectively. Further, the connection board 13 may be arranged at an area except for the center portion of the board. In this way, when the board as a whole is bent, the bent portion is typically the center of the board. Accordingly, such configuration prevents the connection board 13 from being broken by a stress of bending.

Here, the thickness of the connection board 13 may be thinner or thicker than the core layer 11. In this case, if a sheet-shaped resin material is used as a material for the first insulating layer 14A and the second insulating layer 14B, steps might be formed in these insulating layers due to the difference in thickness between the core layer 11 and the connection board 13. However, such formation of the steps is mitigated by applying a liquid resin material as the material for the first insulating layer 14A and the second insulating layer 14B.

Moreover, although only one connection board 13 is shown here, multiple removed areas 12 may be provided to the core layer 11 when necessary, to arrange the connection board 13 in each of these removed areas 12. Alternatively, a relatively large removed area 12 may be formed, and multiple connection boards 13 may be arranged inside this removed area 12.

Furthermore, by forming a wiring pattern of a predetermined shape inside the connection board 13, a capacitor and a coil may be formed. Moreover, a coil, a capacitor, and a resistor may be embedded in the connection board 13, or they may be embedded in the removed area 12 along with the connection board 13 and be connected to each of the wiring layers. With such configuration, the functions of the elements which are, in the prior art, arranged on the upper surface of the board 10A are embedded in the removed area 12 of the core layer 11. Consequently, a circuit device including the board 10A can be reduced in size.

In addition, if a ceramic board is used as the connection board 13, a capacitor and a resistor can easily be provided inside or on a surface of the ceramic board by calcining a conductive material. A board made of ceramic is advantageous over a board made of other materials, because of its performance in high-frequency regions and its high pressure resistance.

The first wiring pattern 15A and the like provided in the connection board 13 are formed finer than the first wiring layer 16A and the like stacked on the core layer 11. The L/S of the first wiring pattern 15A and the like is 30 μm/30 μm or less, for example. By forming such fine conductive patterns in the connection board 13, a part of an electric circuit which is, in the prior art, formed by the wiring layers stacked on the core layer can be formed by the connection board 13. As a result, a circuit part implemented by the first wiring layer 16A to the fourth wiring layer 16D stacked on the core layer 11 is small in size, allowing a size reduction of the board 10A itself.

The first wiring layer 16A and the second wiring layer 16B stacked on the core layer 11 are electrically connected to each other via the connection board 13 having the above configuration. Specifically, the first wiring pattern 15A formed on an upper surface of the connection board 13 is connected to the first wiring layer 16A via the connection portions 31 provided to penetrate the first insulating layer 14A. Further, the fourth wiring pattern 15D provided as the lowermost layer of the connection board 13 is connected to the second wiring layer 16B via the connection portions 33 provided to penetrate the second insulating layer 14B. With such configuration, the first wiring layer 16A located on the upper surface of the core layer 11 is connected to the second wiring layer 16B located on the lower surface of the core layer 11, via the connection board 13.

Note that the first wiring pattern 15A of the connection board 13 and the first wiring layer 16A are connected to each other via the multiple connection portions 31, and that the fourth wiring pattern 15D of the connection board 13 and the second wiring layer 16B are also connected to each other via the multiple connection portions 33. With such configuration, the connection locations at which the wiring layer stacked on the upper surface of the core layer 11 is connected to the wiring layer stacked on the lower surface of the core layer 11 can be concentrated in the connection board 13. As a result, there is no need to provide multiple connection holes shown in the prior art, and therefore the overall size of the board can be reduced. In the above case, the first wiring layer 16A and the second wiring layer 16B that are internally arranged include wiring for routing the connection locations described above.

The wiring patterns of the connection board 13 can also be connected to the third wiring layer 16C or the fourth wiring layer 16D. When the connection board 13 is to be connected to the third wiring layer 16C, the first wiring pattern 15A of the connection board 13 is connected to the third wiring layer 16C by penetrating the first insulating layer 14A and the third insulating layer 14C. Moreover, when the connection board 13 is to be connected to the fourth wiring layer 16D, the fourth wiring pattern 15D of the connection board 13 is connected to the fourth wiring layer 16D by penetrating the second insulating layer 14B and the fourth insulating layer 14D.

In the present embodiment, as described above, the wiring layers stacked at the upper surface of the core layer 11 is connected to the wiring layers stacked at the lower surface of the core layer 11 via the connection board 13 housed in the removed area 12 of the core layer 11. Accordingly, compared with the prior art in which a through-hole is provided to the core layer 11 for each connection portion, an area occupied by the connection portions connecting the upper wiring layers and the lower wiring layers can be reduced. For this reason, the overall size of the board 10A can be reduced.

Further, as described above, the connection board 13 not only functions as connection means, but also can house therein functional elements such as a coil to form a circuit. This contributes to further size reduction and performance enhancement of the board 10A as a whole.

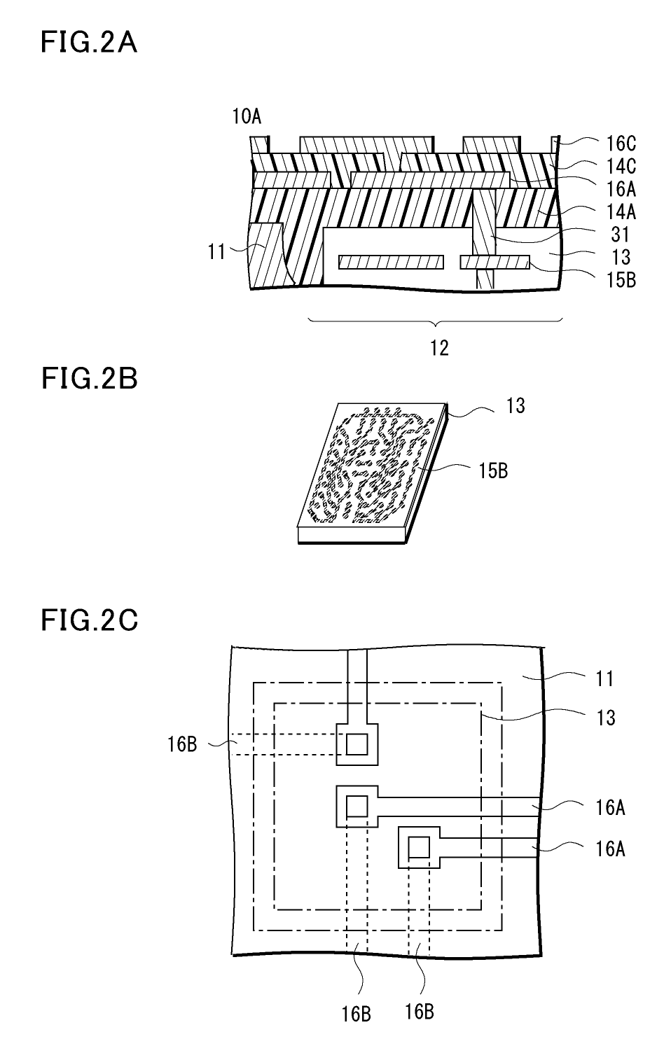

Referring to FIGS. 2A, 2B, and 2C, the configuration of a board 10A is further described.

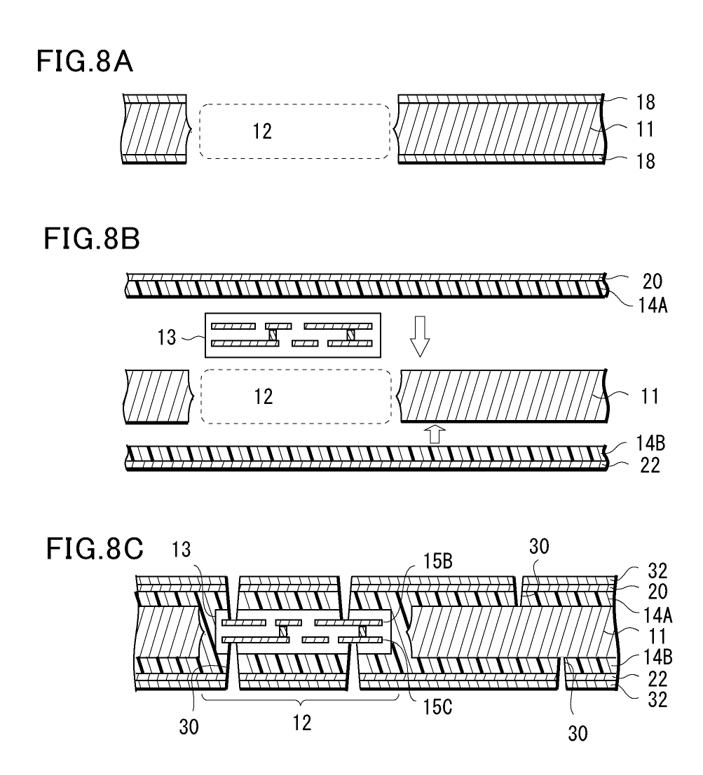

FIG. 2A shows another embodiment, enlarging a part encircled with dots in FIG. 1A. In FIG. 1A, the first wiring pattern 15A being the uppermost layer is arranged on the upper surface of the connection board 13. However, here, a first wiring pattern 15A is not arranged on the upper surface of a connection board 13. Here, the upper surface of the connection board 13 is a surface where an insulating material such as a resin is exposed. Such configuration allows the entire upper surface of the connection board 13 made of an insulating material such as a resin to be in tight contact with a first insulating layer 14A, enhancing the strength of attachment between them. A further description will be given using FIG. 8.

In this configuration, when the connection board 13 is to be connected to a first wiring layer 16A, first, a through-hole is formed by performing laser irradiation to remove the first insulating layer 14A and an insulating material of the connection board 13 under the first insulating layer 14A. Then, a conductive material is embedded in this through-hole to form a connection portion 31. Through this connection portion 31, a second wiring pattern 15B embedded in the connection board 13 is connected to the first wiring layer 16A.

The lower surface of the connection board 13 has such a configuration, too. Specifically, referring to FIG. 1A, the lower surface of the connection board 13 is not provided with a fourth wiring pattern 15D here, but is a surface where a resin material is exposed entirely. This allows the lower surface of the connection board 13 made of an insulating material such as a resin to be in good, tight contact with a second insulating layer 14B. Further, a third wiring pattern 15C of the connection board 13 is connected to a second wiring layer 16B via a connection portion provided to penetrate the second insulating layer 14B and an insulating material of the connection board 13.

FIG. 2B shows the connection board 13 used in such a case. Here, the upper and lower surfaces of the connection board 13 are surfaces where an insulating material such as a resin is exposed entirely. The second wiring pattern 15B provided as the uppermost layer is coated with an insulating material, and is not exposed on the upper surface. Here, the second wiring pattern 15B is shown with dotted lines.

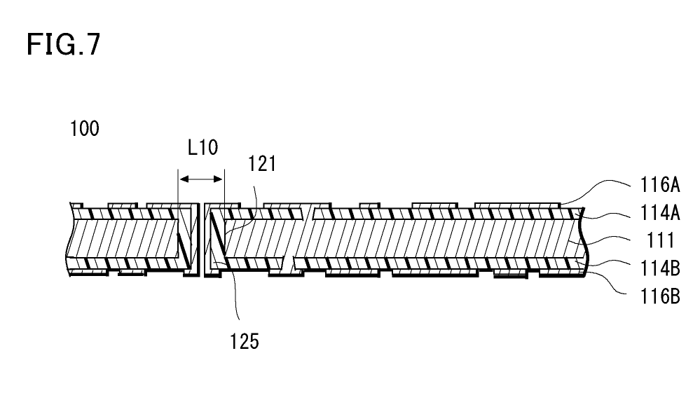

FIG. 2C is a plan view showing the board 10A of a part where the connection board 13 is arranged. Referring to this drawing, in the present embodiment, the first wiring layer 16A arranged on the upper surface of the core layer 11 is connected to the second wiring layer 16B arranged on the lower surface of the core layer 11, with their connection locations being concentrated in the connection board 13. In other words, connection portions penetrating the core layer 11, which are needed to connect the first wiring layer 16A and the second wiring layer 16B, are all foamed in the connection board 13. Accordingly, in the present embodiment, the locations of connection between the first wiring layer 16A and the second wiring layer 16B are rearranged and concentrated in the connection board 13 using these wiring layers. This eliminates the necessity of providing multiple connection portions, which penetrate the core layer 11, discretely in the core layer 11; therefore, the configuration and manufacturing method of the board 10A is simplified, achieving a cost reduction. In FIG. 7, many through-holes are provided at necessary locations in a scattered manner. Since penetration electrodes passes through these through-holes, there may be a problem in a dielectric breakdown voltage. However, since a board made of a resin such as a glass epoxy resin is used as the printed board here, such a problem in a dielectric breakdown voltage is solved.

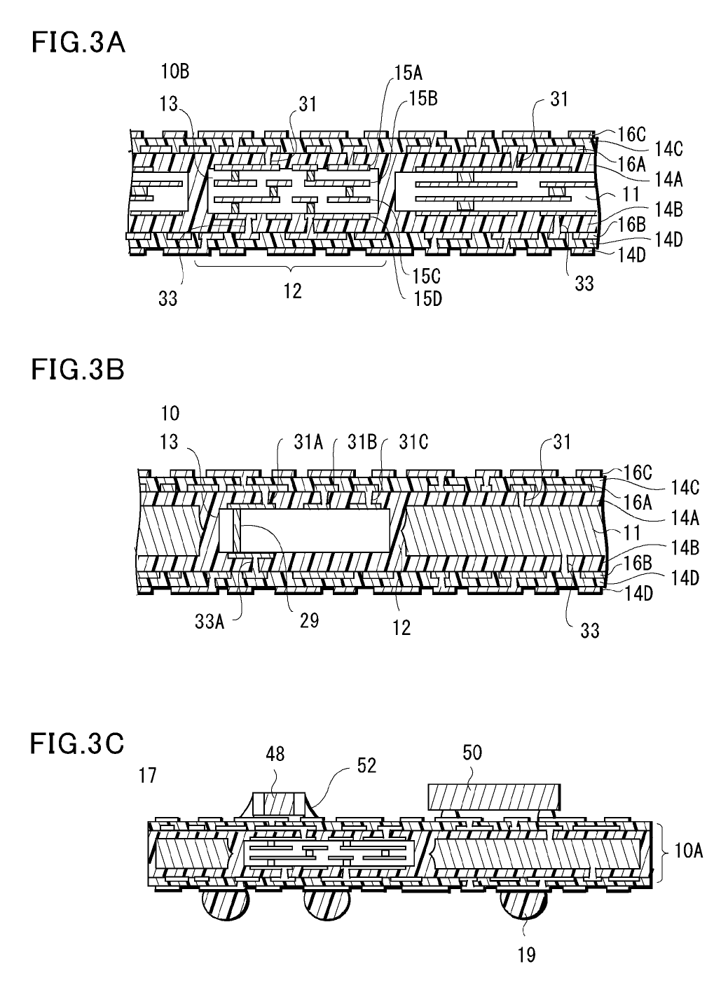

Referring to FIG. 3, a board and a circuit device according to another embodiment is described. FIGS. 3A and 3B are sectional views showing different embodiments, and FIG. 3C is a sectional view of a circuit device employing the board of the present embodiment.

The basic configuration of a board 10B shown in FIG. 3A is similar to that of the board 10A shown in FIG. 1, but is different in that a board including multilayered wiring (four layers here) is used as a core layer 11. For example, a glass epoxy board or a ceramic board including multilayered wiring is used as the core layer 11. Then, a wiring layer provided as the uppermost layer of the core layer is connected to a first wiring layer 16A via connection portions 31. Further, a wiring layer provided as the lowermost layer of the core layer 11 is connected to a second wiring layer 16B via connection portions 33.

When a typical board made of a glass epoxy resin is used as the core layer 11, the L/S of the wiring layers provided to the core layer 11 is in a range of for example, 50 μm/50 μm to 100 μm/100 μm, which is larger than that of the wiring patterns provided to a connection board 13.

The board 10B is formed of a multilayered board as the core layer, such as a printed board or a ceramic board, made of a resin material such as a glass epoxy resin, and therefore can have a more complicated circuit configuration.

In a board 10C shown in FIG. 3B, a board made of semiconductor is used as a connection board 13 included in a removed area 12. A penetration electrode 29 is formed, penetrating the connection board 13 made of semiconductor such as silicon in a thickness direction of the connection board 13. A connection pad, on the connection board 13, connected to the penetration electrode 29 is connected to a first wiring layer 16A via a connection portion 31A. On the other hand, a pad formed on the lower surface of the connection board 13 and in contact with the penetration electrode 29 is connected to a second wiring layer 16B via a connection portion 33A. Thus, the wiring layer arranged on the upper surface of the core layer 11 is electrically connected to the wiring layer arranged on the lower surface of the core layer 11 via the penetration electrode 29 provided in the connection board 13 which is a semiconductor chip. Here, multiple electrodes 29 may be provided in the connection board 13, which is a semiconductor board, to connect the first wiring layer 16A to the second wiring layer 16B at multiple locations via these electrodes.

Further, elements such as a transistor are formed inside the connection board 13, which is a semiconductor board, through a diffusion process, and pads on the upper surface of the connection board 13 that are connected to the elements are connected to the first wiring layer 16A via connection portions 31B and 31C. Heat generated by operation of the transistor and the like provided inside the connection board 13 is dissipated well to the outside through the core layer 11. Here, the pads connected to the diffused regions may be provided on the lower surface of the connection board 13 to connect the pads to the second wiring layer 16B through a connection portion 33.

When a semiconductor board having elements such as a transistor embedded therein is used as the connection board 13 as described above, the board 10C can be provided with more functions.

In FIG. 3C, a circuit device 17 is configured by mounting circuit elements on the upper surface of the board 10A having the above-described configuration. Here, a chip element 48 and a semiconductor element 50 are mounted on the board 10A as the circuit elements. The chip element 48 is a chip capacitor or a chip resistor, and is connected at its both electrodes to the uppermost wiring of the board 10A via a brazing material 52. The semiconductor element 50 is an LSI, and is mounted on the board 10A with its face down via bump electrodes made of solder or the like.

Note that the upper surface of the board 10A may be coated with a resin material such as a glass epoxy resin so as to seal the semiconductor elements. Moreover, the board 10B shown in FIG. 3A or the board 10C shown in FIG. 3B may be used instead of the board 10A.

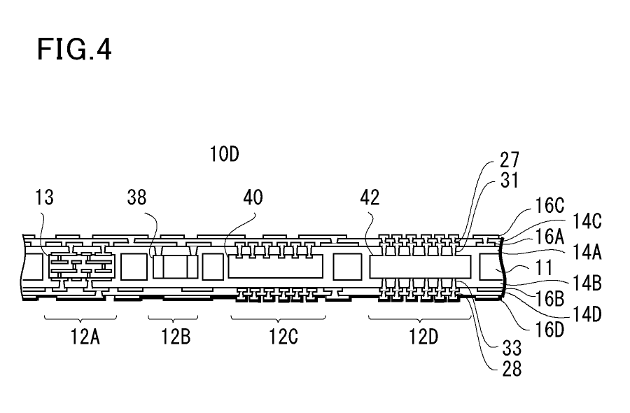

Referring to FIG. 4, the configuration of a board 10D according to a yet another embodiment is described.

The basic configuration of the board 10D is similar to that of the board 10A shown in FIG. 1, but is different from it in that multiple removed areas 12A are provided.

Here, multiple removed areas 12A, 12B, 12C, and 12D are provided by partially removing the core layer 11, and functional elements such as a connection board 13 are housed in these removed areas, respectively.

Specifically, the connection board 13 is housed in the removed area 12A, a chip element 38 in the removed area 12B, a semiconductor element 40 in removed area 12C, and a heat spreader 42 in the removed area 12D. A space between the removed area 12A and the connection board 13 is filled with part of each of insulating layers, and the other removed areas also have such a configuration.

An element having electrodes at its both ends is used as the chip element 38, and is a chip capacitor or a chip resistor, for example. These electrodes are connected to a wiring layer via connection portions. Although the electrodes of the chip element 38 are connected to a first wiring layer 16A via connection portions 31 here, they may be connected to a second wiring layer 16B being a lower layer via connection portions 33.

The semiconductor element 40 is an LSI having many pads on its upper surface, and is arranged with its main surface, having these pads, facing up. The pads arranged on the upper surface of the semiconductor element 40 are connected to the first wiring layer 16A through the corresponding connection portions 31 penetrating a first insulating layer 14A. Further, the second wiring layer 16B, connection portions 28, and a fourth wiring layer 16D are arranged below the semiconductor element 40, and heat generated by the semiconductor element 40 is dissipated well to the outside through them. Here, pads may be provided on the lower surface of the semiconductor element 40 so as to be electrically connected to the second wiring layer 16B via the connection portions 33.

The heat spreader 42 is made of metal having for example copper or aluminum as its main component and having an excellent thermal conductivity, and functions as means that dissipates heat well to the outside, the heat being generated by the circuit elements arranged on the upper surface of the board 10D. The upper surface of the heat spreader 42 is connected to the first wiring layer 16A and a third wiring layer 16C via the connection portions 31 and connection portions 27. Further, the lower surface of the heat spreader 42 is connected to the second wiring layer 16B and the fourth wiring layer 16D via the connection portions 33 and the connection portions 28. Here, a current does not pass through the connection portions with which the heat spreader 42 is connected, but these connection portions function as thermal via holes through which passes heat generated by the circuit elements mounted on the upper surface.

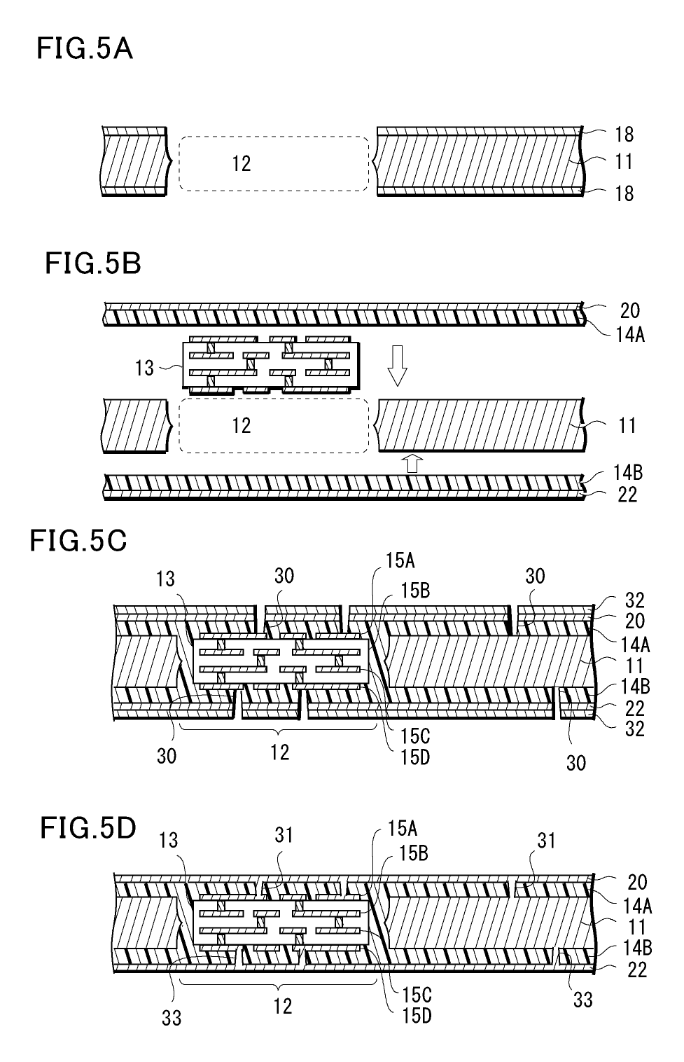

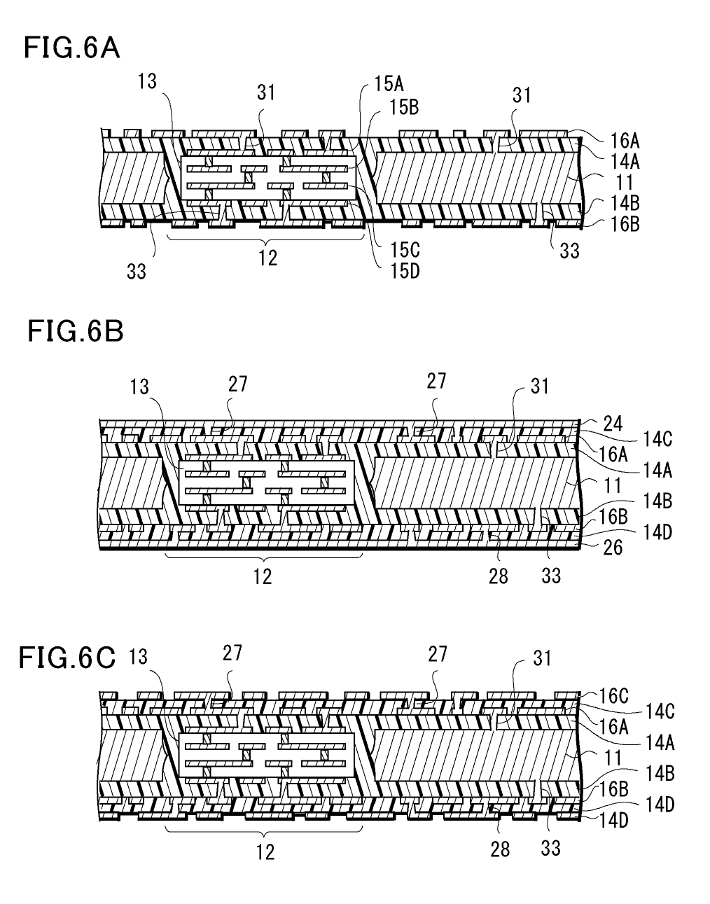

A method of manufacturing the board 10D having the above-described configuration is basically the same a method of manufacturing the board 10A, which will be described later with reference to FIGS. 5 and 6, but is different in that multiple removed areas are provided in the core layer 11 and each house a connection board or one of functional elements.

In the board 10D, the connection portions connecting the wiring layers on the upper surface of the core layer 11 to the wiring layers on the lower surface of the core layer 11 are concentrated in the connection board 13. Thereby, the connection portions which are discretely arranged in the prior art are concentrated in one location. Consequently, the multiple removed areas 12B to 12D can be provided at areas other than a location where the connection board 13 is to be arranged, and the functional elements such as the semiconductor 40 can be embedded in these removed areas 12B to 12D.

Thus, the board 10D on which to mount circuit elements such as a transistor can have various functions in itself, so that a circuit device employing this board 10D can be highly-functional and small in size.

A method of manufacturing the above-described board 10A is described with reference to the sectional views shown in FIGS. 5 and 6.

Referring to FIG. 5A, a core layer 11 made of metal having copper or aluminum as its main component is prepared. The core layer 11 is about 100 μm to 200 μm thick. A removed area 12 is provided by partially removing the core layer 11. A mechanical process method, such as a pressing process or a process using a router, or an etching process is used to form the removed area 12. An etching process is shown in the drawings. To be more specific, both main surfaces of the core layer 11 are covered with an etching resist 18 and are then subjected to an exposure-development process, to be exposed at portions to be removed. Next, wet etching is performed using an etchant to etch the core layer 11 exposed from the resist 18, thereby forming the removed area 12. As a result, as shown in FIG. 5A, inner walls of the removed area 12 each have a projection portion projecting toward the removed area 12 from an opening position of the front surface or the back surface. Since this projection portion is made of metal and therefore may trigger a short circuit, a resin material is embedded in a space between a connection board 13 and the core layer 11, as shown in FIG. 5C. This resin material is a first insulating layer in the drawings, but may be a different material.

Referring to FIG. 5B, subsequently, the connection board 13 is housed in the removed area 12 formed in the above step, and a conductive film to be a material for a wiring layer is stacked on each of both main surfaces of the core layer 11 with an insulating layer interposed therebetween.

Specifically, first, the connection board 13 including multilayered wiring patterns is embedded in the removed area 12. Here, the connection board 13 is connection means which connects wiring layers stacked on the upper surface of the core layer 11 to wiring layers stacked on a lower surface of the core layer 11. In the connection board 13, multiple wiring patterns are stacked with an insulating layer interposed therebetween, and these wiring patterns are formed finer than the wiring layers stacked on the core layer 11.

Next, a conductive film is stacked on each of upper and lower main surfaces of the core layer 11 with an insulating layer interposed therebetween. Specifically, a first conductive film 20 is stacked on the upper surface of the core layer 11 with a first insulating layer 14A interposed therebetween. In addition, a second conductive film 22 is stacked on the lower surface of the core layer 11 with a second insulating layer 14B interposed therebetween. The first insulating layer 14A and the second insulating layer 14B are made of a resin material having a filler mixed therein, and the thickness of each of these insulating layers covering the core layer 11 is 50 μm to 100 μm as described earlier.

The first insulating layer 14A is prepared in a state of being attached to a lower surface of the first conductive film 20, and the second insulating layer 14B is prepared in a state of being attached to an upper surface of the second conductive film 22. Here, each insulating layer may be stacked in a sheet form on the core layer 11 separately from the conductive films. Further, the first insulating layer 14A and the second insulating layer 14B may be applied, in a liquid form, to the upper and lower main surfaces of the core layer 11 and heated and cured thereafter.

The first conductive film 20 and the second conductive film 22 are rolled conductive foil obtained by rolling a conductive material such as copper, and each have a thickness of 20 μm to 50 μm, for example. Besides the rolled conductive foil, a plated film is usable as a material for the first conductive film 20 and the second conductive film 22.

Note that, as a specific method of housing the connection board 13 in the removed area 12, the first conductive film 20 and the second conductive film 22 to each of which the insulating layer is attached as well as the connection board 13 may be stacked and housed collectively, or they may be separately stacked and housed.

To house and stack separately, first, the second conductive film 22 is attached to the lower surface of the core layer 11 with the second insulating layer 14B interposed therebetween. Next, the connection board 13 is housed from above in the removed area 12 whose lower part is plugged by the second conductive film 22 and the second insulating layer 14B. Here, the connection board 13 is fixed at a predetermined position inside the removed area 12 with its lower surface in contact with the second insulating layer 14B. In other words, the second insulating layer 14B in a partially-cured state acts as an adhesive for fixing the connecting board 13 at the predetermined position. Lastly, the first conductive film 20 is attached to the upper surface of the core layer 11 with the first insulating layer 14A interposed therebetween. Here, the removed area 12 is filled with the resin component of the first insulating layer 14A. As a result, a space between the connection board 13 and the side surface of the core layer 11 facing the removed area 12 are filled with part of the first insulating layer 14A and part of the second insulating layer 14B, to thereby determine the position of the connection board 13 inside the removed area 12.

Referring to FIG. 5C, next, the conductive films and the insulating layers are partially removed to form through-holes 30 which are to be connection portions later.

Specifically, first, an upper surface of the first conductive film 20 and a lower surface of the second conductive film 22 are each covered with an etching resist 32. Next, an exposure-development process is performed on the resist 32, so as to expose portions of the upper surface of the first conductive film 20 and of the lower surface of the second conductive film 22, the portions corresponding to areas where the through-holes 30 are to be formed. Then, wet etching is performed using the resist 32 as a mask to remove the portions of the first conductive film 20 and of the second conductive film 22 that are exposed from the resist 32.

Subsequently, after removal of the resist 32, the first insulating layer 14A exposed from the first conductive film 20 is removed by being irradiated with laser, thereby forming the through-holes 30 from which the upper surface of the core layer 11 is exposed. Similarly, the second insulating layer 14B exposed from the second conductive film 22 is removed by being irradiated with laser, thereby forming the through-holes 30 from which the lower surface of the core layer 11 is exposed.

In addition, a first wiring pattern 15A and a fourth wiring pattern 15D of the connection board 13 are also exposed from the through-holes 30 formed in the above manner.

Referring to FIG. 5D, next, connection portions 31 are formed by embedding a conductive material such as a plated film into the through-holes 30 penetrating the first insulating layer 14A. By these connection portions 31, the first wiring pattern 15A being the uppermost layer provided to the connection board 13 is connected to the first conductive film 20 at predetermined positions. Further, in a similar manner, connection portions 31 penetrating the first insulating layer 14A to connect the core layer 11 and the first conductive film 20 are provided. Similarly, connection portions 33 connecting the second conductive film 22 to the core layer 11 are formed. Moreover, connection portions 33 connecting the fourth wiring pattern 15D of the connection board 13 to the second conductive film 22 are formed.

Referring to FIG. 6A, next, selective wet etching is performed on the first conductive film 20 and the second conductive film 22 to form a first wiring layer 16A and a second wiring layer 16B.

Referring to FIG. 6B, next, conductive layers are further stacked with insulating layers interposed. Specifically, a third conductive film 24 is stacked on an upper surface of the first wiring layer 16A with a third insulating layer 14C interposed therebetween, and a fourth conductive film 26 is stacked on a lower surface of the second wiring layer 16B with a fourth insulating layer 14D interposed therebetween. The details of these conductive films and the insulating layers stacked in this step are the same as those of the first insulating layer 14A, the first conductive film 20, and the like described with reference to FIG. 5B.

Connection portions penetrating the insulating layers are also formed in this step. Specifically, connection portions 27 penetrating the third insulating layer 14C are formed to connect the third conductive film 24 and the first wiring layer 16A. In addition, connection portions 28 penetrating the fourth insulating layer 14D are formed to connect the second wiring layer 16B and the fourth conductive film 26. The connection portions 27 and 28 are formed in the same way as the connection portions 31 and 33 shown in FIGS. 5C and 5D.

Referring to FIG. 6C, wet etching is performed on the third conductive film 24 and the fourth conductive film 26 described above to form a third wiring layer 16C and a fourth wiring layer 16D.

The board 10A whose configuration is shown in FIG. 1 is thus configured by the above steps.

Although a total of four wiring layers are stacked on the upper and lower main surfaces of the core layer 11 in the above description, six or more wiring layers may be formed by stacking more wiring layers with insulating layers interposed.

Moreover, referring to FIG. 6C, the third wiring layer 16C and the fourth wiring layer 16D being the uppermost layer and the lowermost layer, respectively, may be covered with a solder resist, except for portions to be connected to circuit elements and the like later.

If a circuit device 17 as shown in FIG. 3C is to be manufactured, a step for mounting circuit elements such as a semiconductor device 50 and a step for welding external electrodes 19 are needed in addition to the above steps.

Further, referring to FIG. 5B, when the connection board 13 is housed in the removed area 12 of the core layer 11, positioning between the core layer 11 and the connection board 13 may be performed using positioning marks as a reference. Specifically, a first mark formed of, for example, part of the conductive pattern is provided to the upper surface of the connection board 13. Moreover, a second mark is provided to the upper surface of the core layer 11 by partially recessing or projecting the upper surface of the core layer 11, for example. Then, to house the connection board 13 into the removed area 12 of the core layer 11, position recognition is performed while imaging them from above using imaging means such as a CCD camera. Then, the planar positions of the connection board 13 and the core layer 11 are adjusted so that the first mark in the connection board 13 and the second mark in the core layer 11 may be in a predetermined positional relation. After this adjustment, the connection board 13 is housed into the removed area 12. By housing the connection board 13 in this way, the connection board 13 is housed at the predetermined position inside the removed area 12, and relative positions of components of the board are improved in accuracy.

Now, the connection board in FIG. 2A is described with reference to FIG. 8.

This drawing is redrawn based on FIG. 5, and does not have the first wiring pattern and the fourth wiring pattern, or has an insulating resin layer, such as a solder resist, provided on each of the first wiring pattern and the fourth wiring pattern. A general board is covered with a solder resist on its outermost surface, and an opening is formed for an electrical connection portion such as a bonding pad or a die pad so as to expose the electrical connection portion. Here, however, no opening is formed, and a front face is covered with the solder resist.

A core layer 11 is etched from both sides as shown in FIG. 8A, and a connection board 13 is embedded as shown in FIG. 8B. Since upper and lower surfaces of the connection board 13 are made of an insulating resin (solder resist), their adhesiveness to a first insulating layer 14A and a second insulating layer 14B can be improved.

Here, sheets in each of which a conductive film is formed on an insulating layer are prepared and attached to the respective sides.

Lastly, after formation of a resist 32, the conductive films are removed through openings of the resist, and holes thus formed in the conductive films are irradiated with laser to form through-holes 30.

Thereafter, steps similar to those in FIG. 6 are carried out.

A molding for sealing may be used for the connection board 13 to embed the wirings inside the connection board 13. Generally, separation of the connection boards is carried out by dicing, and therefore the planar shape of each connection board is a square. However, using a molding enables various structures such as a circle, a triangle, or an L shape.

A description has been given above of board embedment with core metal used as a base. For example, the board in FIG. 1 is suitable for an LED bar. LEDs are mounted in a portion having the core layer, and their drive circuit is arranged on the connection board 13 because an IC and the like are mounted on the drive circuit. Then, if this wiring board is arranged at a periphery of the bar, the main light reflection portion of the bar is not affected.

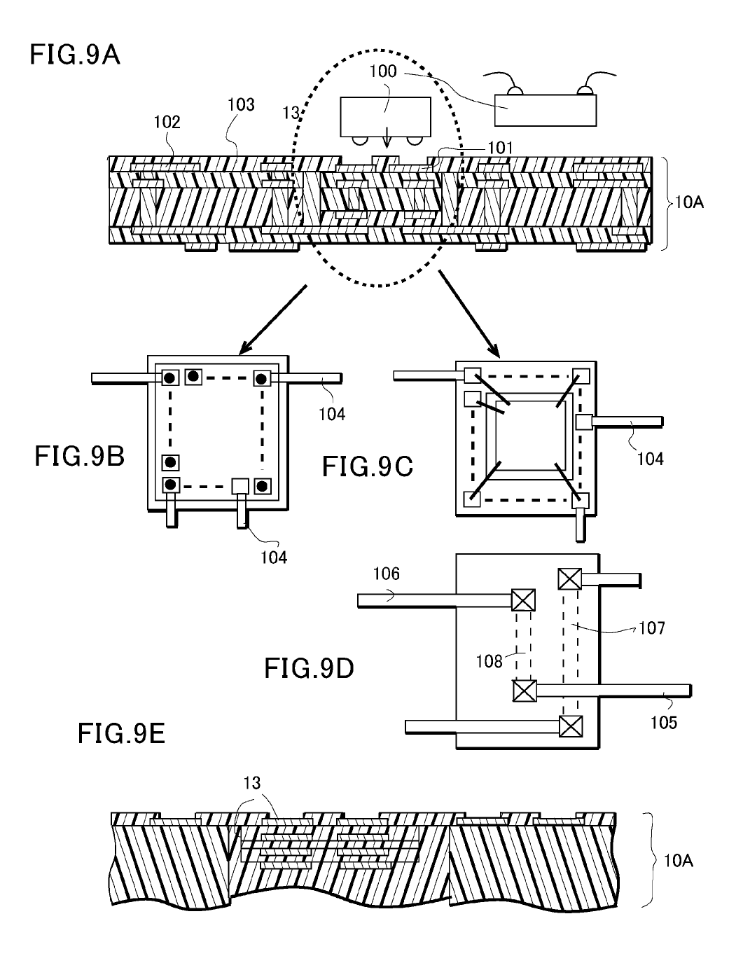

FIG. 9 shows a different embodiment. A module generally employed in a cell phone or the like has a printed board 10A having at least two layers, on which a TR, a chip capacitor, a chip resistor, or an LSI chip 100 is mounted. However, this LSI chip is highly functional, has so many pins, and is small in size. For this reason, the connection board 13 needs to have fine patterns. For example, fine patterns are necessary only for this LSI chip or for the LSI chip and its surrounding circuit, and the board 10A in which the connection board 13 is embedded often has patterns rougher than the connection board.

By enabling the connection board to have highly fine patterns with high density, it is sometimes enough for the board 10A to have rough patterns with low density. Accordingly, the connection board 13 may be embedded in such a manner that a wiring pattern 101 being an outermost surface of the connection board 13 at the front side (or the back side) may be substantially flush with a wiring layer 102 being an outermost surface of the board 10A.

In such a case, a solder resist 103 to be formed on the outermost surface can be formed on the surface of the board 10A and on the surface of the connection board 13 at once. Then, the solder resist at areas corresponding to electrical connection portions only have to be removed. In this way, a cost reduction can be achieved because, while the connection board requires highly accurate processes, the board 10A only requires rough patterns.

In FIG. 9A, the wiring patterns of the connection board on the front and back sides are formed to be substantially flush with the wiring layers of the board 10A. In FIG. 9E, on the other hand, the wiring pattern of the connection board 13 at the front side is formed to be substantially flush with the wiring layer of the board 10A at the front side, and the wiring pattern at the back side is embedded more inward than the wiring layer, which is the outermost surface, of the board 10A at the back side.

The LSI chip 100 is connected to the connection board with its face down in FIG. 9B, and with its face up in FIG. 9C. Then, connection wiring lines 104 are provided from part of a border of the connection board to the board 10A.

In FIG. 9D, no element is mounted, and a board is embedded for crossing avoidance (cross-over). A wiring line 105 extends to a board on the right, and a wiring line 106 extends to a board on the left. Wiring lines 107 and 108 are provided to be buried in the connection board to cross the connection wiring lines. Generally, multilayered wiring is needed when cross-over is necessary. By providing such a wiring board to a part needing cross-over, the number of cross-over points can be reduced to consequently reduce the number of layers of the board itself. For example, a board which would include six layers of wiring if it did not have such a configuration can be implemented with two or four layers.

1. A multilayer printed circuit board of a metal-core type including a metal core layer made of a metal material, as well as at least insulating layers and wiring layers formed on a front surface and a back surface of the metal core layer, respectively, the wiring layers made of a conductor on the respective insulating layers, the multilayer printed circuit board comprising:
at least one removed area provided to penetrate part of the metal core layer; and
a connection board embedded in the removed area, the connection board being formed of a multilayer printed board having a resin core layer made of an insulating material as a base, wherein
the wiring layer on the front surface and the wiring layer on the back surface are electrically connected to each other via the connection board, and
an upper surface, side surfaces, and a lower surface of the connection board are covered with a resin material.

2. The multilayer printed circuit board according to claim 2, wherein
side walls of the removed area each have a projection portion projecting toward the removed area from a position of an opening portion of the removed area, and
a resin material is embedded in a space between the core layer and the circuit board.

3. A multilayer printed circuit board comprising:
a core layer having a first main surface and a second main surface;
a first wiring layer stacked on the first main surface of the core layer with a first insulating layer interposed therebetween;
a second wiring layer stacked on the second main surface of the core layer with a second insulating layer interposed therebetween;
a removed area provided to penetrate part of the core layer;
a connection board being arranged in the removed area and including a plurality of layers of wiring patterns, the connection board functioning as a path connecting the first wiring layer and the second wiring layer, wherein
a first wiring pattern of the connection board located at the first main surface side of the core layer is connected to the first wiring layer via a first connection portion provided to penetrate the first insulating layer,
a second wiring pattern of the connection board located at the second main surface side of the core layer is connected to the second wiring layer via a second connection portion provided to penetrate the second insulating layer, and
an upper surface, side surfaces, and a lower surface of the connection board are covered with a resin material.

4. The multilayer printed circuit board according to claim 3, wherein
the wiring patterns provided in the connection board are formed finer than the first wiring layer and the second wiring layer.

5. The multilayer printed circuit board according to claim 3, wherein
a plurality of the first connection portions are provided, and
a plurality of the second connection portions are provided.

6. The multilayer printed circuit board according to claim 3, wherein
a space between the connection board and inner walls of the core layer that face the removed area is filled with part of the first insulating and part of the second insulating layer.

7. The multilayer printed circuit board according to claim 3, wherein
the core layer is made of metal.

8. The multilayer printed circuit board according to claim 3, wherein
the connection board is a semiconductor board, and
the first wiring layer provided at the first main surface side of the core layer is connected to the second wiring layer provided at the second main surface side of the core layer via a penetration electrode penetrating the semiconductor board.

9. The multilayer printed circuit board according to claim 8, wherein
the semiconductor board includes: an element region formed through a diffusion process; and a pad connected to the element region, and
the pad is connected to the first wiring layer via the first connection portion, or to the second wiring layer via the second connection portion.

10. The multilayer printed circuit board according to claim 3, wherein
the core layer is a substrate made of aluminum, and
the first main surface and the second main surface of the core layer are each covered with an oxide film.

11. The multilayer printed circuit board according to claim 3, wherein
a circuit element is electrically connected to the first wiring layer, and
the second wiring layer functions as an external connection terminal.

12. The multilayer printed circuit board according to claim 3, wherein
the removed area includes a first removed area housing the connection board and a second removed area housing a functional component.

13. The multilayer printed circuit board according to claim 12, wherein
the functional component is a semiconductor element or a chip component.

14. The multilayer printed circuit board according to claim 13, wherein
the functional component includes a heat spreader.

15. The multilayer printed circuit board according to claim 14, wherein
an upper surface of the heat spreader is connected to the first wiring layer via the first connection portion penetrating the first insulating layer, and
a lower surface of the heat spreader is connected to the second wiring layer via the second connection portion penetrating the second insulating layer.

16. A method of manufacturing a multilayer printed circuit board comprising the steps of:
preparing a core layer having a first main surface, a second main surface, and a removed area provided to penetrate part of the core layer;
arranging a connection board in the removed area of the core layer, and covering an upper surface, side surfaces, and a lower surface of the connection board with a resin material, the connection board having a first wiring pattern provided at the first main surface side and a second wiring pattern provided at the second main surface side; and
stacking a first wiring layer on the first main surface of the core layer with a first insulating layer interposed therebetween, stacking a second wiring layer on the second main surface of the core layer with a second insulating layer interposed therebetween, and electrically connecting the first wiring layer to the second wiring layer via the connection board.

17. The method of manufacturing a multilayer printed circuit board according to claim 16, further comprising the steps of:
connecting the first wiring pattern of the connection board to the first wiring layer via a first connection portion penetrating the first insulating layer; and
connecting the second wiring pattern of the connection board to the second wiring layer via a second connection portion penetrating the second insulating layer.

18. The method of manufacturing a multilayer printed circuit board according to claim 16, wherein
a space between the connection board and inner walls of the core layer that face the removed area is filled with part of the first insulating layer and part of the second insulating layer.
